(19) United States
(12) Patent Application Publication
(10) Pub. No.: US 2005/0045979 A1
(43) Pub. Date: Mar. 3, 2005

(54) Light receiving device circuit-built-in type light receiving unit and optical disk unit

(76) Inventors: Tatsuya Morioka, Nara (JP); Shigeki Hayashida, Nara (JP); Yoshihiko Tani, Nara (JP); Isamu Ohkubo, Nara (JP); Hideo Wada, Nara (JP)

Correspondence Address: BIRCH STEWART KOLASCH & BIRCH, PO BOX 747, FALLS CHURCH, VA, 22040-0747, US

(21) Appl. No.: 10/497,242

(22) PCT Filed: Nov. 29, 2002
(86) PCT No.: PCT/JP02/12489

(30) Foreign Application Priority Data
Dec. 3, 2001 (JP) 2001-368402
Jan. 10, 2002 (JP) 2002-003371
Oct. 24, 2002 (JP) 2002-309715

(51) Int. Cl. H01L 27/14

(52) U.S. Cl. 257/432

(57) ABSTRACT

A first P-type diffusion layer and a P-type semiconductor layer are provided on a silicon substrate, and two N-type diffusion layers are provided on a front surface of this P-type semiconductor layer to form two light receiving units. Three-layer translucent films, a first silicon oxide film, a silicon nitride film, and a second silicon oxide film are disposed on the N-type diffusion layers and on the P-type semiconductor layer between the two diffusion layers. Holes produced during a production process and distributed and captured in two interfaces between the three-layer translucent films can reduce a field intensity in the vicinity of the surface of the P-type semiconductor layer to below a conventional level and an inversion of a conductive type to reduce a leak current between the light receiving units accordingly.

This nonprovisional application claims priority under 35 U.S.C. §119(a) on Patent Applications No(s). P2001-368402 filed in Japan on Dec. 3, 2001 and P2002-003371 filed in Japan on Jan. 10, 2002, the entire contents of which are hereby incorporated by reference.

### TECHNICAL FIELD

The present invention relates to a light receiving device, a circuit-built-in type light receiving unit and an optical disk unit.

### BACKGROUND ART

Conventionally, an optical pickup unit for use in optical disk units is structured such that a laser light beam emitted from a semiconductor laser is split into a plurality of laser light beams by a diffraction grating, and a plurality of the laser light beams are collected by an object lens on a plurality of positions on an optical disk, and a plurality of light beams reflected and modulated on the optical disk are received by a light receiving device. The light receiving device, which has a plurality of light receiving parts formed on one semiconductor substrate, outputs a plurality of signals according to the powers of a plurality of the reflected light beams respectively received by a plurality the light receiving parts. Based on a plurality of the signals, a data signal stored in the optical disk, a focus signal for servo control and a tracking signal are generated.

Conventionally, as the light receiving device, there is one that is disclosed in Japanese unexamined patent application No. H10-84102. The light receiving device is structured such that an N-type epitaxial layer is formed on the front surface of a P-type silicon substrate, and the N-type epitaxial layer is divided by a P-type diffusion layer extending to the surface of the P-type silicon substrate to form a plurality of N-type epitaxial regions. A plurality of PN junctions formed between a plurality of the N-type epitaxial regions and the P-type silicon substrate constitute a plurality of light receiving parts. On the N-type epitaxial regions and the P-type diffusion layer, an antireflection structure composed of two layers, a silicon oxide and a silicon nitride, is disposed to prevent incident light to a plurality of the light receiving parts from reflecting and to improve sensitivity of the light receiving device.

When being mounted on an optical disk unit, the light receiving device is required high sensitivity to have a good S/N ratio. For example, in the case of receiving red laser light having wavelength of 400 nm, the above-stated conventional light receiving device is given the antireflection structure composed of two-layer films, a silicon oxide with a thickness of 10 nm and a silicon nitride with a thickness of 39 nm, so as to set the reflectance of the laser light at almost 0% to achieve excellent sensitivity.

However, there is a problem that the conventional device is susceptible to leak current between a plurality of the light receiving parts, and at worst, leak current between the light receiving parts becomes too large for the light receiving device to function properly. The problem is attributed to holes stored in an interface between the silicon oxide and the silicon nitride forming the antireflection structure. Electric fields generated by the stored holes inverses a conductive type of the P-type diffusion layer between a plurality of the N-type epitaxial regions, and leak current between the N-type epitaxial regions flows in a part where a conductive type is inverted. It was found out that the holes stored in the interface of the antireflection structure are generated during a production process of the light receiving device by exposure to plasma in a dry etching step or by static charges generated in a dicing step. Therefore, the conventional light receiving device has poor production yield and higher costs, which poses a problem of inadequacy as an optical disk unit.

Further, in the conventional light receiving device, if the surface of the antireflection structure is exposed to air, the silicon nitride on the surface of the antireflection structure gradually oxidizes and therefore a reflectance of the antireflection structure is changed. Consequently, a reflectance of the incident light to the antireflection structure changes, and so a power of light reaching the light receiving parts changes, resulting in change in signal values outputted by the light receiving device. This leads to a problem of inappropriate read of data from a disk.

The above problems become more notable as incident light to the light receiving device has longer wavelength. This is because shot-wavelength light has strong oxidation and particularly light with wavelength of not larger than 500 nm has strong oxidation, so that upon incidence of such short-wavelength light, the layer on the surface of the antireflection structure rapidly oxidizes. Another reason is that in the antireflection structure, change in reflectance caused by change in refraction index is larger when the wavelength of incident light is smaller. According to these reasons, the conventional light receiving device suffers rapid oxidation of the surface layer of the antireflection structure upon reception of short-wavelength light, and so the reflectance on the surface of the antireflection structure is drastically changed by the oxidation, by which the power of light reaching the light receiving parts is significantly changed from the power of incident light, causing drastic change in signal outputs. Therefore, there is a problem that the conventional light receiving device is not adequate for receiving short-wavelength light.

Accordingly, it is a primary object of the present invention to provide a light receiving device, a circuit-built-in type light receiving unit and an optical disk unit, that can be produced almost free from leak current and in good yield, that have an antireflection film composed of multi-layer films less susceptible to oxidation and have a stable signal output characteristic, and that are suitable for receiving short-wavelength light.

### DISCLOSURE OF THE INVENTION

In order to achieve the above object, the present invention provides a light receiving device comprising a plurality of light receiving parts disposed on a semiconductor layer, wherein
three or more-layer translucent films are disposed on the plurality of the light receiving parts and on a part between the plurality of the light receiving parts, and materials of the translucent films adjacent to each other are different from each other.

According to the above configuration, three or more-layer translucent films are disposed on the light receiving parts and on the part between the plurality of the light receiving parts in the light receiving device, and materials of the adjacent translucent films are different from each other, so that two or more interfaces are formed between these three or more-layer translucent films. Electrons or holes produced, for example, during a production process, are distributed and stored in the above-stated two or more interfaces. Conventionally, the electrons and the holes are stored in one interface between two-layer translucent films. Therefore, the light receiving device of the present invention is smaller in intensity of electric fields that are formed in the light receiving parts and in the part between the light receiving parts by the stored electrons or holes than the conventional light receiving device. As a result, inversion of a conductive type is reduced in the part between the plurality of the light receiving parts. Therefore, current hardly flows in the part between the plurality of the light receiving parts, and therefore leak current between the light receiving parts is effectively controlled.

Further, since three or more-layer translucent films are disposed in the light receiving device, and the materials of the adjacent translucent films are different from each other, the film thicknesses of the translucent films are set at specified thicknesses corresponding to the wavelength of light received by the light receiving device so as to effectively decrease the reflectance of the light that comes incident to the light receiving device. Therefore, sensitivity of the light receiving device is effectively enhanced.

Here, the semiconductor layer refers to a semiconductor formed in a layer state and includes a semiconductor substrate. Also, the light receiving part refers to a minimum part that is formed on the semiconductor layer and has a photoelectric transfer effect.

In one embodiment, one of the translucent films is a silicon oxide and another one of the translucent films is a silicon nitride.

According to the above embodiment, constituting the translucent films from the silicon oxide and the silicon nitride makes it possible to provide a light receiving device easily and inexpensively by a general process, that is almost free from leak current, small in reflectance to incident light and is excellent in sensitivity. Here, the number of the silicon oxide and the number of the silicon nitride may be one or more each.

In one embodiment, one of the translucent films is a titan oxide.

According to the above embodiment, the titan oxide constituting one of the translucent films is relatively high in refraction index, so that combining it with a film with a refraction index smaller than that of the titan oxide such as silicon oxide makes it possible to effectively reduce the reflectance of incident light to the light receiving device. Further, the titan oxide is relatively high in refraction index, so that if air or other substances are present outside the translucent films having the titan oxide, the reflectance on the surface of the light receiving device remains almost unchanged. Therefore, even if the light receiving device is, for example, molded with resin, the reflectance is almost the same as the case without resin molding, and therefore it is not necessary to change an output characteristic with respect to a power of received light with or without resin molding. As a result, it is not necessary to change a drive circuit of the light receiving device corresponding to application of resin molding. Conventionally, in the case of a light receiving device having two-layer translucent films on the surface of the light receiving device, it was not possible to set the reflectance on the surface of the light receiving device with resin molding equal to the reflectance without resin molding even if the thickness of the translucent films is optimized.

In one embodiment, the translucent film closest to the light receiving parts among the translucent films is a silicon oxide, and a thickness of the silicon oxide is not smaller than 10 nm.

According to the above embodiment, the translucent film closest to the light receiving parts among the translucent films is formed as a silicon oxide with a thickness of not smaller than 10 nm, so that electrons or holes captured between the silicon oxide and the translucent film disposed thereon are kept away from the light receiving parts and from the part between the light receiving parts so as to reduce an influence of electric fields caused by the electric charges in the light receiving parts and in the part between the light receiving parts. As a result, it becomes possible to control inversion of a conductive type in the part between the light receiving parts for effectively decreasing leak current between the light receiving parts. Here, if the thickness of the translucent film closest to the light receiving parts is smaller than 10 nm, then leak current in the part between the light receiving parts is increased.

The present invention also provides a light receiving device comprising: light receiving parts disposed on a semiconductor layer; and at least translucent films laminated on the light receiving parts, wherein
the uppermost layer among the translucent films is an oxide.

According to the above configuration, the uppermost layer among the translucent films is an oxide, and this oxide is relatively less susceptible to oxidation, so that the translucent films scarcely oxidizes even when exposed to air. Therefore, the refraction index of the translucent films remains almost unchanged and so the reflectance also remains almost unchanged. Therefore, in the light receiving device, a power of light before coming incident to the light receiving device is almost the same as to a power of light in the light receiving parts during operation for a long period of time. As a result, the light receiving device can obtain stable signal output values. Further, even if a light received by the light receiving device is short-wavelength light, the uppermost film among the translucent films is an oxide, so that the translucent films do not easily oxidize, and so the reflectance of the translucent films remains almost unchanged. As a result, even if short-wavelength light is received, a stable signal output characteristic can be obtained, which makes the light receiving device suitable for light with short wavelength.

Further, the translucent films allow effective reduction of the reflectance of the entire translucent films by adjusting each film thickness, thereby allowing provision of a high-sensitivity light receiving device.

In one embodiment, the translucent films are composed of a first silicon oxide, a first silicon nitride, and a second silicon oxide laminated in sequence from a side of the light receiving parts.

According to the above embodiment, the uppermost film among the translucent films is a silicon oxide that is relatively insusceptible to oxidation, which makes it possible to prevent change in signal output value of the light receiving device attributed to oxidation of the translucent films as seen in the conventional example and allows provision of the light receiving device with a stable output characteristic. Further, corresponding to the wavelength of incident light to the light receiving device, the thickness of the first silicon oxide, the first silicon nitride and the second silicon oxide is respectively regulated so as to effectively reduce the entire reflectance of the translucent films to the incident light with the above wavelength.

In one embodiment, the translucent films are composed of a first silicon oxide, a first silicon nitride, a second silicon oxide, a second silicon nitride and a third silicon oxide laminated in sequence from a side of the light receiving parts.

According to the above embodiment, the uppermost film among the translucent films is a silicon oxide that is relatively insusceptible to oxidation, which makes it possible to prevent change in signal output value of the light receiving device attributed to oxidation of the translucent films and allows provision of the light receiving device with a stable output characteristic. Further, corresponding to the wavelength of incident light to the light receiving device, the thickness of the first silicon oxide, the first silicon nitride, the second silicon oxide, the second silicon nitride and the third silicon oxide is respectively regulated so as to effectively reduce the entire reflectance of the translucent films to the incident light with the above wavelength.

Further, the translucent films are composed of a first silicon oxide, a first silicon nitride, a second silicon oxide, a second silicon nitride and a third silicon oxide, so that if a translucent resin and the like is disposed on the translucent films, the translucent films still obtain low reflectance without being affected by the resin.

The present invention also provides a circuit-built-in type light receiving unit comprising: the light receiving device and a signal processing circuit for processing a signal from the light receiving parts of the light receiving device, each formed on an identical semiconductor substrate.

According to the above configuration, the signal processing circuit is formed in a monolithic state, which makes it possible to provide a circuit-built-in type light receiving unit that is almost free from leak current and that has excellent sensitivity.

The present invention also provides an optical disk unit comprising the light receiving device or the circuit-built-in type light receiving unit.

According to the above configuration, the light receiving device or the circuit-built-in type light receiving unit that is almost free from leak current and has excellent sensitivity is provided, which makes it possible to provide an optical disk unit suitable for read and write access to a high-density storage optical disk with use of, for example, a blue laser.

### BRIEF DESCRIPTION OF THE DRAWINGS

FIG. 1A is a plan view showing a light receiving device in a first embodiment of the present invention, while FIG. 1B is a cross sectional view of FIG. 1A taken on the line I-I′;

FIG. 2 is a graph with respect to the light receiving device in FIG. 1A and a conventional light receiving device showing changes in leak current generated between cathodes of a plurality of light receiving parts when an applied voltage is changed;

FIG. 3 is a cross sectional view showing a light receiving device in a second embodiment of the present invention;

FIG. 4 is a cross sectional view showing a light receiving device in a third embodiment of the present invention;

FIG. 5A is a plan view showing a light receiving device in a fourth embodiment of the present invention, while FIG. 5B is a cross sectional view of FIG. 5A taken on the line II-II′;

FIG. 6 is a cross sectional view showing a light receiving device in a fifth embodiment of the present invention;

FIG. 7 is a graph with respect to light receiving devices having a first silicon oxide different in thickness from each other showing changes in leak current when an applied voltage is changed;

FIG. 8 is a cross sectional view showing a light receiving device in a sixth embodiment of the present invention;

FIG. 9 is a view showing a circuit-built-in type light receiving unit in a seventh embodiment of the present invention; and

FIG. 10 is a view showing an optical disk unit in an eighth embodiment of the present invention.

### BEST MODE FOR CARRYING OUT THE INVENTION

Embodiments of the invention will now be described in detail with reference to the accompanying drawings.

First Embodiment:

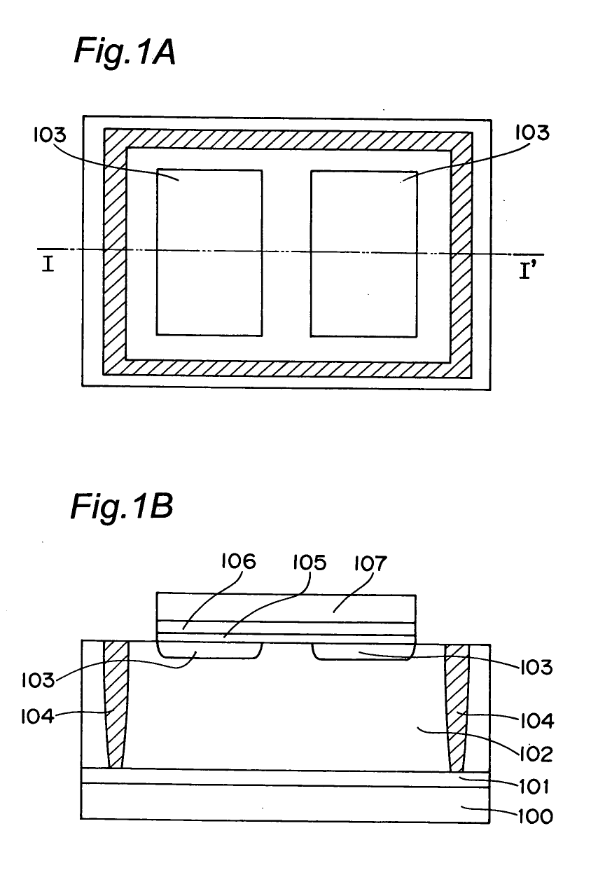

FIG. 1A is a plan view showing a light receiving device in a first embodiment of the present invention, while FIG. 1B is a cross sectional view of FIG. 1A taken on the line I-I′. In FIGS. 1A and 1B, contacts, metal interconnections, and interlayer insulating films formed after a contact step are deleted. In FIG. 1A, a first silicon oxide 105, a silicon nitride 106 and a second silicon oxide 107 are deleted.

The light receiving device comprises a first P-type diffusion layer 101 with impurity concentration of about 1E18 cm⁻³ and a thickness of about 1 μm, and a P-type semiconductor layer 102 with a thickness of about 10 μm to 20 μm and impurity concentration of about 1E13 to 1E16 cm⁻³ on a silicon substrate 100. In a surface part of the P-type semiconductor layer 102, two N-type diffusion layers 103, 103 with impurity concentration of about 1E17 to 1E20 cm⁻³ are disposed to constitute two light receiving parts. In the N-type diffusion layers 103, any element such as arsenic, phosphorus, and antimony may be diffused or doped as long as the element is pentavalent.

In the vicinity of opposite ends of the P-type semiconductor layer 102 in FIG. 1B, there are formed second P-type diffusion layer portions 104, 104 extending from a top surface of the P-type semiconductor layer 102 to the first P-type diffusion layer 101 for establishing electrical contact between the first P-type diffusion layer 101 and the top surface of the P-type semiconductor layer 102. The second P-type diffusion layer 104 is formed, as shown in FIG. 1A, so as to surrounding the periphery of the N-type diffusion layers 103, 103. In the first and second P-type diffusion layers 101, 104, any element such as boron and indium may be diffused or doped as long as the element is triatomic.

On the N-type diffusion layers 103, 103 and on a part between these two N-type diffusion layers 103, 103, there are disposed in sequence a first silicon oxide 105, a silicon nitride 106 and a second silicon oxide 107 as translucent films. The first silicon oxide 105 that is closest to the N-type diffusion layers 103 is about 9 nm in thickness, and the silicon nitride 106 is 39 nm in thickness, and the second silicon oxide 107 is 280 nm in thickness.

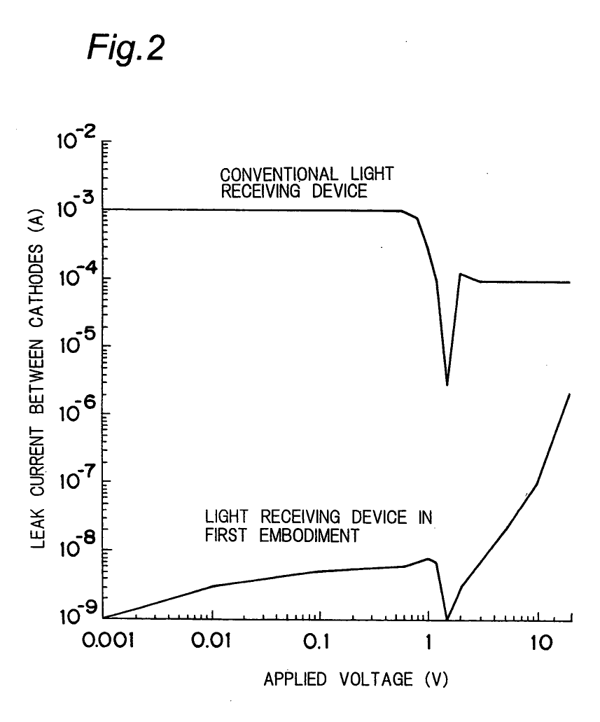

FIG. 2 is a graph with respect to the above-configured light receiving device and a conventional light receiving device having two-layer translucent films showing changes in leak current generated between cathodes of a plurality of light receiving parts when a voltage applied between electrodes is changed. In the light receiving device of the present embodiment and the conventional light receiving device, one electrode voltage is kept 1.5V while a voltage applied to the other electrode is changed. In FIG. 2, a horizontal axis represents applied voltage values (V) while a vertical axis represents current values (A) between cathodes of the light receiving parts.

In the light receiving device of the present invention, during normal operation, a voltage of 1.5V is applied to the both electrodes. However, due to variation in circuits to which the voltage is applied or in power supply voltage, a voltage applied to the electrode varies by about 0.3V around 1.5V. As shown in FIG. 2, in this variation range of the applied voltage, the light receiving device of the present invention gains a current value between the cathode of the light receiving parts of 10⁻⁹A order, thereby implementing effective restraint of leak current.

This is because holes are captured in interfaces formed between a plurality of the translucent films as adjacent translucent films being different from each other in band structure, and also the interfaces are formed at two locations composed of a first interface between the first silicon oxide 105 and the silicon nitride 106 and a second interface between the silicon nitride 106 and the second silicon oxide 107. By this, holes generated in a plasma etching step or a dicing step during a production process are distributed and captured in the interfaces formed at two locations, so that a field intensity that causes the inversion of a conductive type in the semiconductor layer provided in the light receiving parts is reduced lower than that in the conventional case where holes are captured in one interface. Further, the second interface is positioned farther than the first interface for a thickness of the silicon nitride 106, so that on the surface of the P-type semiconductor layer 102, an intensity of the fields caused by the holes captured in the second interface is reduced below an intensity of the fields caused by the holes captured in the first interface. Therefore, an intensity of the fields caused by the holes distributed and captured in the two interfaces is smaller than a conventional intensity of the fields caused by the holes captured in one interface. Since an intensity of the fields caused by the holes is reduced, a conductivity type is hardly inverted in the part of the P-type semiconductor layer 102 between the N-type diffusion layers 103, 103. This makes it possible to effectively prevent inversion of a part of the P-type semiconductor and abnormal leak current flowing between the light receiving parts through this inversion part.

Further, the light receiving device of the present invention include three-layer translucent films, the thickness of the translucent films is so set that the a silicon oxide 105 is about 9 nm in thickness, a silicon nitride 106 is about 39 nm in thickness, and a second silicon oxide 107 is about 280 nm in thickness, which makes it possible to set the reflectance at several % that is almost equal to the reflectance in the case of the conventional two-layer translucent films. Here, setting the thickness of the second silicon oxide 107 at 250 nm to 310 nm enables the reflectance with the three-layer translucent films to be equal to the reflectance with the conventional two-layer translucent films.

In the above embodiment, although the N-type diffusion layers 103, 103 are formed in the P-type semiconductor layer 102 to constitute the light receiving parts, a plurality of light receiving parts may formed in other configurations.

Further, without being limited to the first silicon oxide 105 and the second silicon oxide 107, the translucent films may use a nitride oxide containing nitrogen. Particularly, in the case of using a silicon nitride oxide instead of the first silicon oxide 105, carriers in the light receiving device are prevented from being leaked in an oxide and being stored in an interface of the films.

Further, in the light receiving device of the present invention, the uppermost layer in a plurality of the translucent films is the second silicon oxide 107, so that if the translucent films are operated in the state of being exposed to air, the surface does not easily oxidize. Even if the light receiving device receives, for example, short-wavelength light having wavelength of 405 nm and having strong oxidation, oxidation of a plurality of the translucent films can be effectively prevented by the second silicon oxide 107. Therefore, unlike the conventional case, oxidation does not progress from the surface exposed to air to change a refraction index of the antireflection film and a reflectance, and so a power of light reaching the light receiving parts is not changed from a power of incident light, preventing an output characteristic from being changed. As a result, the light receiving device has a stable output characteristic even if receiving short-wavelength light for a long time, and is capable of accurately output signals corresponding to incident light over a long period of time.

Further in the above embodiment, the second silicon oxide 107 may perform other functions such as being used as an interlayer insulating film, which makes it possible to reduce the number of production steps of the light receiving device.

Second Embodiment:

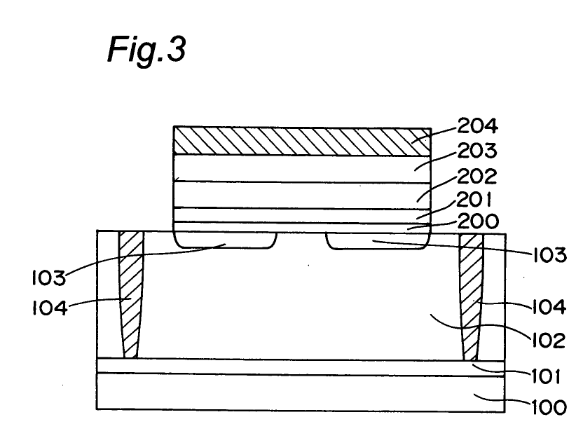

FIG. 3 is a cross sectional view showing a light receiving device in a second embodiment of the present invention. In FIG. 3, component members having the same functions as the light receiving device in the first embodiment of FIG. 1B are designated by the same reference numerals and detailed description is deleted.

As shown in FIG. 3, the light receiving device in the present embodiment is different from the light receiving device in the first embodiment only in the point that on the N-type diffusion layers 103, 103 becoming light receiving parts and on the P-type semiconductor layer 102 between these two N-type diffusion layers 103, 103, four-layer translucent films are formed and a molding resin 204 is disposed on the translucent films.

The four-layer translucent films are composed of a first silicon oxide 200 with a film thickness of about 9 nm, a first silicon nitride 201 with a film thickness of about 39 nm, a second silicon oxide 202 with a film thickness of about 250 nm, and a second silicon nitride 203 with a film thickness of about 120 nm formed in the order from the side closer to the light receiving parts.

The light receiving device includes the above-stated four-layer translucent films and has three interfaces among the translucent films. Holes generated during a production process or the like are distributed to and captured by the three interfaces and are farther away from the surface of the P-type semiconductor layer 102 than the first embodiment, so that an intensity of the fields caused by the holes can be further reduced. Therefore, the inversion of a conductivity type in the part of the P-type semiconductor layer 102 between the N-type diffusion layers 103, 103 can be effectively prevented, resulting in achieving effective reduction of leak current between the cathodes of the light receiving parts.

Conventionally, if a light receiving device having two-layer translucent films is coated with resin on a top surface of the translucent films, then a reflectance to incident light is increased higher than that of the light receiving device without the resin coating. For example, in the case where the conventional light receiving device having two-layer translucent films has resin coating, it was not possible to decrease the reflectance to 15% or smaller even if the thickness of the translucent films is optimized. In contrast to this, the light receiving device of the present embodiment has four-layer translucent films, so that adjusting each thickness and refraction index of the four-layer translucent films makes it possible to reduce the reflectance to almost 0 both in the case with resin coating and in the case without resin coating. Therefore, the light receiving device can equalize an output characteristic with respect to a power of received light irrespective resin coating, so that it is not necessary to change a drive circuit corresponding to differences in optical system such as resin coating being applied or not. As a result, the light receiving device needs only one drive circuit, which can decrease production costs.

Third Embodiment:

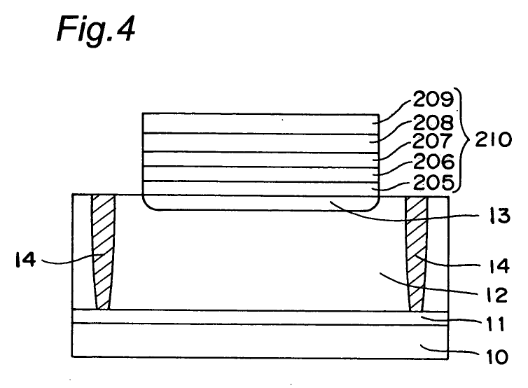

FIG. 4 is a cross sectional view showing a light receiving device in a third embodiment of the present invention. In the present embodiment, contacts, metal interconnections, interlayer insulating films and the like formed after a contact step are deleted in description.

The light receiving device comprises a P-type diffusion layer 11 with impurity concentration of about 1E18 cm⁻³ and a thickness of about 1 μm on a silicon substrate 10, and a P-type semiconductor 12 with impurity concentration of about 1E13 to 1E16 cm⁻³ and a thickness of about 10 μm to 20 μm on the P-type diffusion layer 11. On a surface part of the P-type semiconductor 12, an N-type diffusion layer 13 with impurity concentration of 1E17 to 1E20 cm⁻³ in the vicinity of the surface is provided, and a PN junction formed by the N-type diffusion layer 13 and the P-type semiconductor 12 constitutes a light receiving part. It is to be noted that an impurity forming the N-type diffusion layer 13 may be any element such as arsenic, phosphorus, and antimony as long as the element is pentavalent.

In the vicinity of the both ends of the P-type semiconductor layer 12 in FIG. 4, there is formed a P-type diffusion layer portions 14, 14 so as to extend from a top surface of the P-type semiconductor layer 12 to the P-type diffusion layer 11 for establishing electrical contact. It is to be noted that an impurity forming the P-type diffusion layers 11, 14 is any element such as boron and indium as long as the element is triatomic.

On the P-type semiconductor 12 and on the light receiving part, there is provided an antireflection film 210 formed in a normal silicon process. The antireflection film 210 is composed of a plurality of translucent films, which are made up of five layers, a first silicon oxide 205, a first silicon nitride 206, a second silicon oxide 207, a second silicon nitride 208, and a third silicon oxide 209 in the order from the side closer to the light receiving part. The silicon oxides forming the antireflection film have a refraction index of 1.47 and the silicon nitrides have a refraction index of 2.07. The first silicon oxide 205 is formed to have a thickness of 16 nm, the first silicon nitride 206 is formed to have a thickness of 33 nm, the second silicon oxide 207 is formed to have a thickness of 69 nm, the second silicon nitride 208 is formed to have a thickness of 49 nm, and the third silicon oxide 209 is formed to have a thickness of 139 nm. By this, the reflectance of the entire antireflection film to incident light having wavelength of 405 nm is set at 1%.

In the above-configured light receiving device, the uppermost film of the antireflection film 210 is the third silicon oxide 209, so that the antireflection film 210 hardly oxidize even if it is operated in the state of being exposed to air. Therefore, unlike the conventional case, oxidation of the antireflection film to change a refraction index and a reflectance as well as to change signal output values of the light receiving device with respect to a power of incident light are effectively prevented. Further, by regulating the thickness of five films constituting the antireflection film 210, the reflectance of the entire antireflection film to incident light having wavelength of 405 nm is set at 1%, which makes it possible to provide a light receiving device with excellent sensitivity. Therefore, the light receiving device can sustain good characteristics for a long period of time even if it receives short-wavelength light with relatively strong oxidation.

Here, the light receiving device in the second embodiment has three translucent films, and in such a case, coating the surface of the light receiving device with translucent resin disables the reflectance to light with wavelength of 405 nm from being reduced below 10%. Contrary to this, the light receiving device in the third embodiment has the antireflection film 210 composed of five films, and so if the light receiving device is coated with translucent resin, the reflectance of the antireflection film 210 can be reduced to 1% just like the case without translucent resin coating. As a result, in the light receiving device in the present embodiment, signal output values corresponding to incident light are identical in the case with resin molding and in the case without resin molding, which makes it unnecessary to separately produce signal processing circuits depending on application of the resin molding for the light receiving device. Therefore, the light receiving device can gain versatility at low costs.

Further, the films constituting the antireflection film 210 may also perform other functions such as an interlayer insulating function, which makes it possible to reduce the number of production steps of the light receiving device. In the case of applying translucent resin coating, the thickness of the third silicon oxide 209, the uppermost layer of the antireflection film 210, does not affect the reflectance of the antireflection film 210. Therefore, in this case, the silicon oxide 209 may be given a thickness so as to function as an interlayer insulating film.

In the above embodiment, if each refraction index of a plurality of films constituting the antireflection film 210 and the wavelength of incident light are not those as described above, regulating the thickness of each film makes it possible to set the reflectance at about 1%.

Further in the above embodiment, although the N-type diffusion layer 13 is formed on the surface part of the P-type semiconductor 12 to constitute the light receiving part, the N type semiconductor layer may be laminated on the P-type semiconductor layer to constitute the light receiving part.

Further, although one light receiving part is provided in the above embodiment, a plurality of light receiving parts may be provided.

Further in the above embodiment, although the antireflection film 210 is disposed on the P-type semiconductor 12 and on the light receiving part, the antireflection film may be disposed on the entire surface of the P-type semiconductor 12.

In the light receiving device of the above embodiment, N type and P type in the part that constitutes the light receiving device may be interchanged.

Fourth Embodiment:

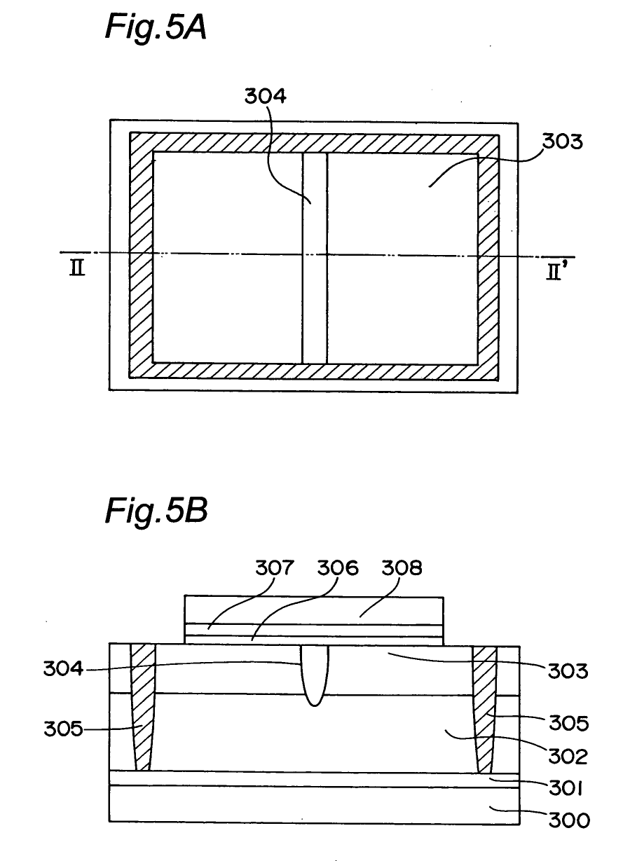

FIG. 5A is a plan view showing a light receiving device in a fourth embodiment of the present invention, while FIG. 5B is a cross sectional view of FIG. 5A taken on the line II-II′. In FIGS. 5A and 5B, contacts, metal interconnections, and interlayer insulating films formed after a contact step are deleted. In FIG. 5A, a first silicon oxide 306, a titan oxide 307 and a second silicon oxide 308 are deleted.

The light receiving device of the present embodiment is composed of a P-type diffusion layer 301 with a thickness of about 1 μm and impurity concentration of about 1E18 cm⁻³, and a P-type semiconductor layer 302 with a thickness of about 10 μm to 20 μm and impurity concentration of about 1E13 to 1E16 cm⁻³ on a silicon substrate 300. On the P-type semiconductor layer 302, there are provided N-type diffusion layers 303, 303 with a thickness of about 1 to 3 μm and impurity concentration of about 1E16 to 1E17 cm⁻³.

The N-type diffusion layers 303, 303 are formed by laminating N-type semiconductors on the P-type semiconductor layer 302, and the N-type semiconductors are separated by a P-type diffusion layer 304 extending from the top surface to the P-type semiconductor layer 302. The N-type diffusion layers 303, 303 constitute light receiving parts. In the both end portions of the N-type diffusion layers 303, 303 and the P-type semiconductor layer 302 in FIG. 5B, there is provided a P-type diffusion layer 305. The P-type diffusion layer 305 makes it possible to establish electrical contact between the top surface of the N-type diffusion layers 303, 303 and the P-type diffusion layer 301.

On light incidence parts of the N-type diffusion layers 303, 303 and on the surface of the P-type diffusion layer 304, there is disposed three-layer translucent films. The three-layer translucent films are composed of a first silicon oxide 306 with a thickness of about 9 nm, a titan oxide 307 with a thickness of about 30 nm, and a second silicon oxide 308 with a thickness of about 210 nm formed in the order from the side closer to the surface of the N-type diffusion layers 303, 303.

The light receiving device of the present embodiment has the three-layer translucent films and has an interface at two locations, which makes it possible to reduce the number of holes captured by each of the interfaces less than the conventional light receiving device which has two-layer translucent films so that holes are captured by one interface. Therefore, an intensity of the fields on the surface of the P-type diffusion layer 304 is reduced below a conventional level. Further, the holes captured by the interface between the titan oxide 307 and the second silicon oxide 308 are isolated from the surface of the P-type diffusion layer 304 by the first silicon oxide 306 and the titan oxide 307. Therefore, the fields caused by the holes captured in between the titan oxide 307 and the second silicon oxide 308 are significantly smaller in intensity on the surface of the P-type diffusion layer 304. Therefore, the inversion of a conductive type in the P-type diffusion layer 304 can be effectively prevented, resulting in effective restraint of abnormal leak current between the cathodes of the light receiving parts.

Further, the light receiving device of the present embodiment uses a titan oxide having a refractive index larger than that of a silicon oxide, so that the reflectance of incident light to the light receiving device can be decreased smaller than that in the case of using the silicon nitride. More specifically, in the case of resin coating is applied, the light receiving device composed of the first silicon oxide 105, the silicon nitride 106 and the second silicon oxide 107 in the first embodiment has a surface reflectance of approx. 15%, whereas the light receiving device composed of the first silicon oxide 306, the titan oxide 307, and the second silicon oxide 308 in the present embodiment can have a surface reflectance of approx. 0%.

Also, the light receiving device of the present embodiment has the titan oxide 307 as the uppermost layer of a plurality of the translucent films, which makes it possible to effectively prevent oxidation of a plurality of the translucent films.

Fifth Embodiment:

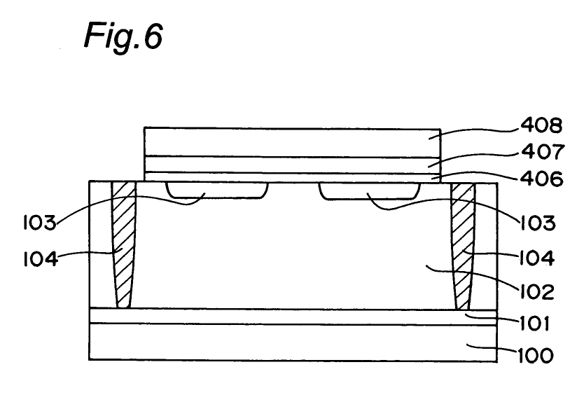

FIG. 6 is a cross sectional view showing a light receiving device in a fifth embodiment of the present invention. The light receiving device is composed of a silicon substrate 100, a first P-type diffusion layer 101, a P-type semiconductor layer 102, and N-type diffusion layers 103, 103 formed on the P-type semiconductor layer 102 similar to the first embodiment. On the P-type semiconductor layer 102 and on the N-type diffusion layers 103, 103, there are provided three-layer translucent films composed of a first silicon oxide 406, a silicon nitride 407 and a second silicon oxide 408. The film thickness of the silicon nitride 407 is about 33 nm, while the film thickness of the second silicon oxide 408 is about 70 nm. In the present embodiment, the first silicon oxide 406 is given different thicknesses, and a voltage of 1.5V is applied to one electrode of the light receiving device while a voltage applied to the other electrode is changed to examine a leak current characteristic between the N-type diffusion layers 103, 103 that are light receiving parts. The leak current becomes a noise component in photocurrent outputted when light comes incident to the light receiving device. Normally, dark current generated in a light receiving device with a size of about several hundred μm is about several pA, so that it is necessary to keep leak current between the cathodes to about several pA (pico-Ampere) or lower for restraining a current that becomes a noise component of the entire light receiving device.

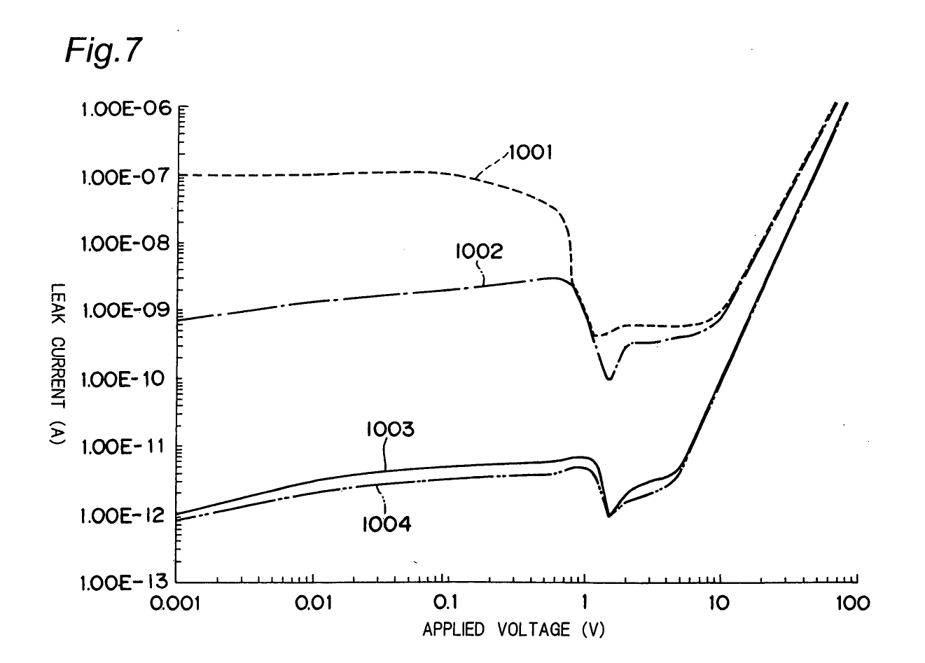

FIG. 7 is a graph showing changes in leak current when an applied voltage is changed, in which a curve 1001 representing the first silicon oxide 406 with a thickness of 5 nm, a curve 1002 with a thickness of 7 nm, a curve 1003 with a thickness of 10 nm and a curve 1004 with a thickness of 16 nm are superposed.

As shown in FIG. 7, as the thickness of the first silicon oxide 406 increases from 5 nm to 7 nm, leak current is reduced in all the applied voltages. Further, as the thickness of the first silicon oxide 406 increases to 10 nm, the leak current is further reduced in all the applied voltages. Here, during normal operation of the light receiving device, a voltage of 1.5V is applied to the both electrodes. However, due to variation in circuit by which the light receiving device is driven or in supply voltage, a voltage applied to the both electrodes sometimes varies by about 0.3V around 1.5V. In such a case, the leak current between the light receiving parts can be an order of pA. As the thickness of the first silicon oxide 406 increases to 16 nm, the leak current decreases lower than that in the case where the thickness of the first silicon oxide 406 is 10 nm. This implies that setting the thickness of the first silicon oxide 406 at not smaller than 10 nm allows effective reduction of the leak current and effective restraint of a noise component in an output signal.

It is to be noted that in the case of four-layer translucent films, the four-layer translucent films can distribute holes so as to reduce fields in the vicinity of the P-type semiconductor layer 102 more than the three-layer translucent films can, so that setting the silicon oxide disposed so as to be in contact with the surface of the P-type semiconductor layer 102 at not smaller than 10 nm makes it possible to reduce the leak current generated by the inversion of a conductivity type of the P-type semiconductor layer 102 to a sufficiently small pA order. When four-layer translucent films composed of a silicon oxide with a film thickness of about 16 nm, a silicon nitride with a film thickness of about 33 nm, a silicon oxide with a film thickness of about 64 nm and a silicon nitride with a film thickness of about 49 nm were actually disposed on the surface of the P-type semiconductor layer 102, leak current flowing in a part of the P-type semiconductor layer 102 between the light receiving parts could be a sufficiently small pA order.

Sixth Embodiment:

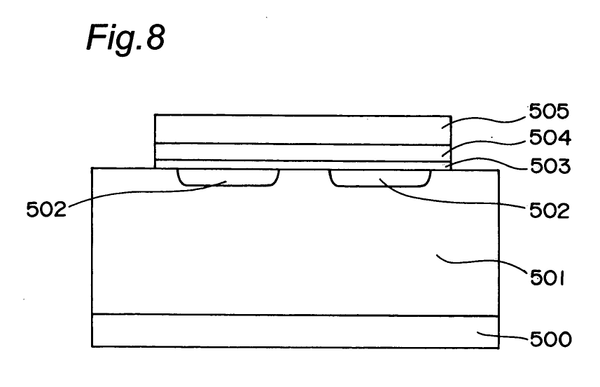

FIG. 8 is a cross sectional view showing a light receiving device in a sixth embodiment of the present invention. The light receiving device has a P-type GaN epitaxial layer 501 with a thickness of about 15 μm and impurity concentration of about 1E13 to 1E16 cm⁻³ on a P-type GaN (gallium nitrogen) substrate 500 with impurity concentration of about 1E19 cm⁻³. In a surface part of the P-type GaN epitaxial layer 501, two N-type diffusion layers 502, 502 with impurity concentration of about 1E17 to 1E20 cm⁻³ on the surface are disposed to constitute light receiving parts. It is to be noted that the N-type diffusion layers 502, 502 may be formed, for example, by pentavalent silicon ion implantation.

In the light receiving device, at least on the light receiving parts and on a part of the P-type GaN epitaxial layer 501 between the light receiving parts, three-layer translucent films are provided. The three-layer translucent films are composed of a first silicon oxide 503 with a film thickness of 9 nm, a silicon nitride 504 with a film thickness of about 39 nm and a second silicon oxide 505 with a film thickness of about 210 nm in the order from the side closer to the P-type GaN epitaxial layer 501. The three-layer translucent films makes it possible to set the surface reflectance of incident light to the light receiving device at about 3%. Also in the present embodiment, holes generated during a production process and the like can be distributed and captured in the three-layer translucent films having two interfaces. Further, with the interface between the silicon nitride 504 and the second silicon oxide 505, the holes can be captured in the state of being isolated from the surface of the P-type GaN epitaxial layer 501. Therefore, in the vicinity of the surface of the P-type GaN epitaxial layer 501, the inversion of a conductive type due to the fields formed by the holes can be prevented, and so the leak current between the cathodes of the light receiving parts can be effectively prevented.

In the present embodiment, although the substrate and the epitaxial layer on the substrate are composed of GaN, they may be composed of III-V based compound semiconductor such as gallium arsenide, gallium aluminum arsenide and indium phosphorus group, II-VI based compound semiconductor such as zinc selenide, or mixed crystal of these.

Seventh Embodiment:

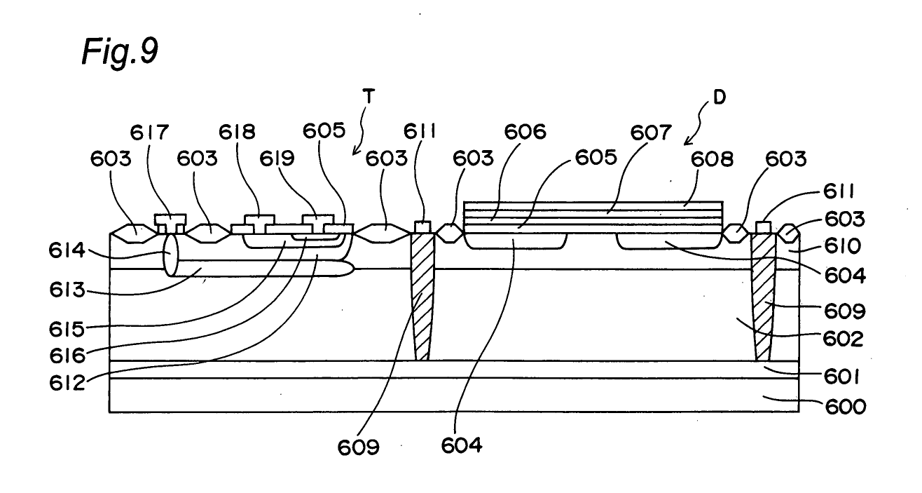

FIG. 9 is a view showing a circuit-built-in type light receiving unit in a seventh embodiment of the present invention. The circuit-built-in type light receiving unit is composed of a light receiving device D of the present invention and a bipolar transistor T for processing a signal from the light receiving device formed on the same semiconductor substrate. In FIG. 9, multilevel interconnections, interlayer films and the like that are formed after the step for processing metal interconnections are deleted.

The circuit-built-in type light receiving unit in the present embodiment is composed of a first P-type diffusion layer 601 with a thickness of 1 to 2 μm and boron concentration of about 1E18 to 1E19 cm⁻³, and a first P-type semiconductor layer 602 with a thickness of 15 to 16 μm and boron concentration of about 1E13 to 1E14 cm⁻³ formed on a silicon substrate 600 with boron concentration of about 1E15 cm⁻³. In a part of the region in which a bipolar transistor is formed on the first P-type semiconductor layer 602, there is provided an N-type diffusion layer 613 becoming a collector. On the first P-type semiconductor layer 602 and the N-type diffusion layer 613, there is formed a second P-type semiconductor layer 610 with thickness of 1 to 2 μm and boron concentration of about 1E13 to 1E14 cm⁻³. In a part of a top surface of the second P-type semiconductor layer 610, a plurality of LOCOS regions 603, 603, . . . are formed for element isolation.

In the region in which the light receiving device D is formed and in a surface part of the second P-type semiconductor layer 610, there are formed two N-type diffusion layers 604, 604 with phosphorus concentration of 1E19 to 1E20 cm⁻³ and a junction depth of about 0.3 to 0.8 μm to form light receiving parts. On the light receiving parts and on a part of the second P-type semiconductor layer 610 between the light receiving parts, four-layer translucent films are disposed. The four-layer translucent films are composed of a first silicon oxide 605 with a film thickness of about 16 nm, a first silicon nitride 606 with a film thickness of 33 nm, a second silicon oxide 607 with a film thickness of 210 nm, and a second silicon nitride 608 with a film thickness of 200 nm formed in the order from the side closer to the second P-type semiconductor layer 610. Throughout the first P-type semiconductor layer 602 and the second P-type semiconductor layer 610, there is formed a second P-type diffusion layer 609 for connecting the first P-type diffusion layer 601 as an interconnection and the top surface of the second P-type semiconductor layer 610.

In the region in which the bipolar transistor T is formed and in the second P-type semiconductor layer 610, there is formed an N-type well structure 612 with phosphorus concentration of 2E15 to 2E16 cm⁻³ so as to be positioned above the N-type diffusion layer 613. In a part of the N-type well structure 612, there is formed a P-type semiconductor layer with boron concentration of 1E17 to 2E17 cm⁻³ to constitute a base 615 of the transistor. Further, in a surface part of the P-type semiconductor layer constituting the base 615, there is formed an N-type semiconductor layer by solid diffusion with arsenic-doped polysilicon to constitute an emitter 616 of the transistor.

In the light receiving device D, there are formed an unshown cathode electrode and an anode electrode 611, while in the bipolar transistor T, there are formed a collector electrode 617, a base electrode 618 and an emitter electrode 619. With the above configuration, a circuit-built-in type light receiving unit that is almost free from leak current in the light receiving device D and that has good characteristics was achieved.

In the present embodiment, although an NPN transistor is used, a PNP transistor may be used, and further both the NPN type and PNP type transistors may be used either. Furthermore, without being limited to the configuration of the present embodiment, the transistor may employ other configurations.

Eighth Embodiment:

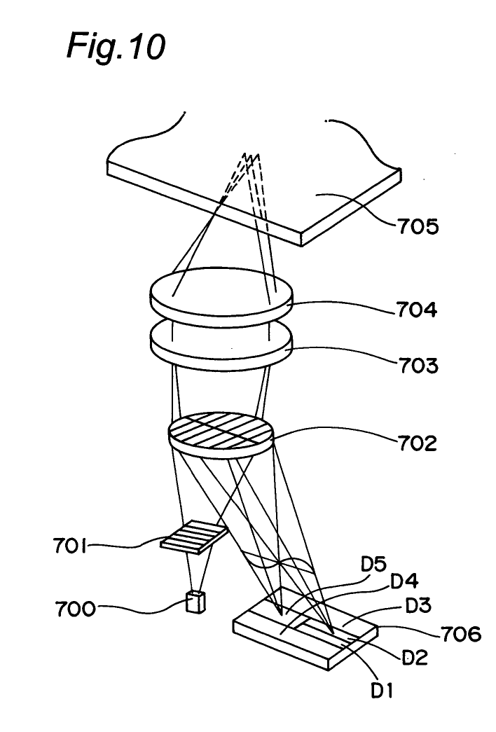

FIG. 10 is a view showing an optical disk unit in an eighth embodiment of the present invention. The optical disk unit includes the light receiving device of the present invention.

The optical disk unit, which has a blue light emitting semiconductor laser 700, splits light emitted from the semiconductor laser 700 into two side beams for tracking and one main beam for reading signals with use of a diffraction grating 701. After transmitted through a hologram element 702 as zero-order light and converted to parallel light by a collimate lens 703, these beams are collected on a disk 705 by an object lens 704. The collected light is reflected on the disk 705 while its light power is modulated by a pit formed on the disk 705, and the modulated reflected light comes incident to hologram element 702 through the object lens 704 and the collimate lens 703. The incident light is then diffracted by the hologram element 702, and diffracted first-order light comes incident to five light receiving parts D1 to D5 of a light receiving device 706. Then, output signals from the receiving device 706 corresponding to the incident light to these five light receiving parts are added to and subtracted from each other, thus a reading signal and a tracking signal are obtained.

The above-described optical disk unit includes the light receiving device 706 of the present invention, which has little leak current between the light receiving parts and has a relatively small reflectance to incident light, thereby making it possible to provide an optical disk unit allowing high-speed read access to high-density optical disks.

In this embodiment, a circuit-built-in type light receiving unit may be provided instead of the light receiving device 706. In this case, the circuitry of the optical disk unit can be simplified.

Further, without being limited to the optical system in the present embodiment, the optical disk unit may use other optical systems.

Further, a semiconductor laser that emits, for example, red light, other than blue light may be used.

In the light receiving device of the present embodiment, N type and P type in the part that constitutes the light receiving device may be interchanged. In such a case, electrons are stored in interfaces between a plurality of translucent films and an intensity of fields formed by these electrons can be reduced below a conventional level, so that the inversion of an conductive type in the part between the light receiving parts in the semiconductor layer is effectively avoided, resulting in effective decrease in leak current between a plurality of light receiving parts.

Further, the light receiving device 706 has a plurality of translucent films of the present invention, so that even if blue light from the semiconductor laser 700 is continuously received, the reflectance of the translucent films remains almost unchanged, allowing provision of an optical disk unit having stable good characteristics.

As is clear from the above description, according to the light receiving device of the present invention, in a light receiving device composed of a plurality of light receiving parts disposed on a semiconductor layer, three or more-layer translucent films are disposed on the light receiving parts and on a part between a plurality of the light receiving parts, and materials of the adjacent translucent films are different from each other, which makes it possible to distribute and store electrons or holes generated during a production process or the like in an interface formed at two or more locations, thereby making it possible to reduce an intensity of fields formed in the light receiving parts and in the part between the light receiving parts below a conventional level. Consequently, it becomes possible to prevent the inversion of a conductive type in the part between a plurality of the light receiving parts and to restrain leak current between a plurality of the light receiving parts. Further, in the light receiving device, setting the film thickness of the translucent films at a specified thickness allows effective decrease in reflectance of light that comes incident to the light receiving device, which makes it possible to effectively enhance sensitivity of the light receiving device.

Further, according to the light receiving device of the present invention, in a light receiving device composed of a light receiving part disposed on a semiconductor layer and at least a plurality of translucent films laminated on the light receiving part, the uppermost layer among a plurality of the translucent films is an oxide, by which the translucent films hardly oxidize even if a short-wavelength light passes in the state of being exposed to air, and therefore the refraction index of a plurality of the translucent films is almost unchanged so that the reflectance is also almost unchanged. Therefore, a ratio of a power of light in the light receiving parts to a power of light that comes incident to a plurality of the translucent films is retained even for a long period of time, which makes it possible to provide a light receiving device with stable operation even upon reception of short-wavelength light.

According to the circuit-built-in type light receiving unit of the present invention, the light receiving device and a signal processing circuit for processing a signal from a plurality of the light receiving parts of the light receiving device are formed on an identical semiconductor substrate, which makes it possible to provide a circuit-built-in type light receiving unit that is almost free from leak current and has excellent sensitivity.

According to the optical disk unit of the present invention, the light receiving device or the circuit-built-in type light receiving unit is provided, which makes it possible to provide an optical disk unit suitable for read and write access to high-density storage optical disks with use of, for example, blue laser light source.

1. A light receiving device, comprising: a plurality of light receiving parts disposed on a semiconductor layer; and
three or more-layer translucent films disposed on the plurality of the light receiving parts and on a part between the plurality of the light receiving parts, wherein translucent films adjacent to each other are of different materials.

2. The light receiving device as defined in claim 1, wherein
one of the translucent films is a silicon oxide and another one of the translucent films is a silicon nitride.

3. The light receiving device as defined in claim 1, wherein
one of the translucent films is a titan oxide.

4. The light receiving device as defined in claim 1, wherein
the translucent film closest to the light receiving parts among the translucent films is a silicon oxide, and a thickness of the silicon oxide is not smaller than 10 nm.

5. The light receiving device as defined in claim 1, wherein
the uppermost layer among the translucent films is an oxide.

6. The light receiving device as defined in claim 1, wherein
the translucent films are composed of a first silicon oxide, a first silicon nitride, and a second silicon oxide laminated in sequence from a side of the light receiving parts.

7. The light receiving device as defined in claim 1, wherein
the translucent films are composed of a first silicon oxide, a first silicon nitride, a second silicon oxide, a second silicon nitride and a third silicon oxide laminated in sequence from a side of the light receiving parts.

8. A circuit-built-in type light receiving unit, comprising: the light receiving device as defined in claim 1 and a signal processing circuit for processing a signal from the light receiving parts of the light receiving device, each formed on an identical semiconductor substrate.

9. An optical disk unit comprising the light receiving device as defined in claim 1.

10. An optical disk unit comprising the circuit-built-in type light receiving unit as defined in claim 8.
